(19) United States
(12) Patent Application Publication
(10) Pub. No.: US 2013/0050468 A1
(43) Pub. Date: Feb. 28, 2013

(54) INSPECTION SYSTEM AND A METHOD FOR INSPECTING MULTIPLE WAFERS

(71) Applicants: Gilad Golan, Raanana (IL); Arnon Ben Natan, Kiriat Tivon (IL); Omri Katz, Haifa (IL); Michael Vainer, Yokneam (IL)

(72) Inventors: Gilad Golan, Raanana (IL); Arnon Ben Natan, Kiriat Tivon (IL); Omri Katz, Haifa (IL); Michael Vainer, Yokneam (IL)

(73) Assignee: CAMTEK LTD., Migdal Haemek (IL)

(21) Appl. No.: 13/563,768

(22) Filed: Aug. 1, 2012

Related U.S. Application Data
(60) Provisional application No. 61/525,971, filed on Aug. 22, 2011.

(51) Int. Cl. H04N 7/18; H01L 21/683

(52) U.S. Cl. 348/87; 211/41.18; 348/E07.085

(57) ABSTRACT

A method and an inspection system that includes: a multi wafer support device arranged to concurrently support multiple wafers; optics arranged to acquire images of the multiple wafers supported by the multi wafer support element;

a mechanical stage arranged to introduce movement between the multi wafer support element and the optics; and
a processor arranged to process the images acquired by the optics.

### RELATED APPLICATION

This application claims priority from U.S. provisional patent 61/525971 filing date Aug. 22 2011 which is incorporated herein by reference.

### BACKGROUND

The semiconductor HBLED (High Brightness LED) manufacturing is going through a rapid growth due to the vast usage in hope lighting, LCD backlight, automotive industry and the like.

This trend and the relative simplicity of the manufacturing of HBLED calls for newcomers (such as in Taiwan & China) to enter this market and both the competition and the market demand the drop of price of HBLED.

Typically such manufacturing starts from 2 Inch wafers and moving to 4 Inch wafers where the most advanced today apply 6 Inch wafer technology, but still, a huge part of the market resides in the 2 Inch and 4 Inch wafer segments.

AOI is integral part of the manufacturing process of HBLED and as such also suffer from the pressure to reduce cost of ownership (COO).

The current solutions in the industry apply a “single wafer scan” which includes Load/unload, optical character recognition (OCR) or other identification information (ID) reading process, alignment and image acquisition (scan).

The highest throughput available today is limited to 140 WPH (wafers per hour) for 2 Inch wafers.

As the wafer is small, scan time is relatively short so the other operations yield very high percentage as overheads.

### SUMMARY OF THE INVENTION

According to an embodiment of the invention an inspection system may be provided and may include a multi wafer support device that may be arranged to concurrently support multiple wafers; optics that may be arranged to acquire images of the multiple wafers supported by the multi wafer support element; a mechanical stage that may be arranged to introduce movement between the multi wafer support element and the optics; and a processor that may be arranged to process the images acquired by the optics.

The multi wafer support device may include a multi wafer tray and a chuck.

The chuck may be transparent and the multi wafer tray may define multiple cavities for receiving the multiple wafers without concealing a backside of the multiple wafers.

The inspection system may include a backside illumination unit that may be arranged to illuminate a backside of the multiple wafers.

The multi wafer tray may have, at a bottom of each of the cavities, a transparent and flexible bottom element that contacts the transparent chuck.

The chuck may be arranged to flatten the transparent and flexible bottom element of each cavity.

The multi wafer tray may have, at a bottom of each of the cavities, a transparent bottom element that contacts the transparent chuck.

The multi wafer tray may define multiple cavities for receiving the multiple wafers and the multi wafer tray may have, at a bottom of each of the cavities, a flexible bottom element that contacts the transparent chuck.

The chuck may be arranged to flatten the flexible bottom element of each cavity.

The chuck may be at least partially opaque.

The chuck may include at least one illumination element that may be arranged to illuminate the multiple wafers. [gg1]

The multi wafer support device may include a bottom interfacing element and a frame, the frame comprises grooves that that may be arranged to receive interfacing elements of a load and unload mechanism, wherein the bottom interfacing element may be arranged to support the chuck and to be placed above the grooves.

The inspection system may include a load and unload mechanism that may be arranged to place the multi wafer tray, the chuck and bottom interfacing element on the frame while contacting the bottom interfacing element and then withdraw from the grooves.

The multi wafer tray may be arranged to support multiple wafers that are spaced apart from each other and that may be arranged in a two-dimensional array.

The inspection system may be arranged to scan one wafer after the other.

The inspection system may be arranged to scan multiple portions of a plurality of wafers before completing a scan of an entire single wafer. For example, the inspection system may scan the multi wafer tray by a raster scan pattern that scans multiple slices of the multi wafer tray, each slice includes images of portions of a plurality of wafers.

Additional embodiments of the invention include a method that can be executed by any of the systems described above. For example, the method may include:

Loading a multi wafer support device that may be arranged to concurrently support multiple wafers;

Acquiring images of the multiple wafers supported by the multi wafer support element by optics while introducing movement, between the multi wafer support element and the optics; and

Processing, by a processor, the images acquired by the optics.

The method may include illuminating, by a backside illumination unit, a backside of the multiple wafers. This may be useful for obtaining transmissive mode images of the multiple wafers. This may also be used for obtaining images of the backside of the multiple wafers. Thus may assist in reading text that appears at the backside of the wafers—wherein the reading may involve OCR.

The multi wafer support device may include a multi wafer tray that may define multiple cavities for receiving the multiple wafers, wherein there is a flexible bottom element at the bottom of each cavity. The method may include flattening, by the chuck, the flexible bottom element of each cavity.

The method may include illuminating the multiple wafers by at least one illumination element of the chuck. The method may include illuminating the multiple wafers by illumination elements that are spaced apart from the chuck.

The method may include unloading the multi wafer support device to a cassette. The cassette may also store wafers of size that match the size of the multi wafer tray.

The method may include placing, by the load and unload mechanism, the multi wafer tray, the chuck and bottom interfacing element on the frame while contacting the bottom interfacing element; and withdraw the interfacing elements from the grooves.

The method may include scanning, by the optics, one wafer after the other.

The method may include scanning, by the optics, multiple portions of a plurality of wafers before completing a scan of an entire single wafer.

A multi wafer support device may be provided and may include a multi wafer tray and a chuck; wherein the multi wafer tray defines multiple cavities for receiving multiple wafers; wherein the multi wafer tray has, at a bottom of each of the cavities, a flexible bottom element that contacts the chuck; wherein the chuck is arranged to flatten the flexible bottom element of each cavity.

The chuck may be transparent or at least partially opaque.

The chuck may include at least one illumination element arranged to illuminate the multiple wafers.

The multi wafer support device may also include a bottom interfacing element and a frame, the frame comprises grooves that are arranged to receive interfacing elements of a load and unload mechanism, wherein the bottom interfacing element is arranged to support the chuck and to be placed above the grooves.

The chuck may be transparent and each of the flexible bottom elements may be transparent.

A multi wafer support device may be provided and may include a multi wafer tray and a chuck; wherein the chuck is transparent and the multi wafer tray defines multiple cavities for receiving the multiple wafers without concealing a backside of the multiple wafers.

The multi wafer tray may have, at a bottom of each of the cavities, a transparent bottom element that contacts the chuck.

Each transparent bottom element may be flexible and the chuck may be arranged to flatten the flexible bottom element of each cavity and to flatten the wafer supported by the flexible bottom element.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 illustrates a multi wafer tray according to an embodiment of the invention;

FIG. 2A illustrates a multi wafer tray and a frame according to an embodiment of the invention;

FIG. 2B is a cross sectional view of a portion of a multi wafer support device and of a wafer according to an embodiment of the invention;

FIG. 3 is exploded view of a multi wafer support device and of a frame according to an embodiment of the invention;

FIG. 4 is exploded view of a multi wafer support device and of a frame according to an embodiment of the invention;

FIG. 5 is exploded view of a multi wafer support device and of a frame according to an embodiment of the invention;

FIG. 6 illustrates a wafer identification unit, a multi wafer tray and an end effector according to an embodiment of the invention;

FIG. 7 illustrates an inspection system according to an embodiment of the invention;

FIG. 8 illustrates a scanning pattern according to an embodiment of the invention; and

FIG. 9 illustrates method according to an embodiment of the invention;

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE DRAWINGS

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Because the illustrated embodiments of the present invention may for the most part, be implemented using electronic components and circuits known to those skilled in the art, details will not be explained in any greater extent than that considered necessary as illustrated above, for the understanding and appreciation of the underlying concepts of the present invention and in order not to obfuscate or distract from the teachings of the present invention.

There is provided an inspection system and a method that dramatically increase the throughput of inspection.

The inspection system can achieve a throughput that may exceed 200 WPH and even 500 WPH.

The inspection system and method can reduce ration between load/unload and scan per wafer by loading and unloading multiple wafers at once and by scanning the multiple wafers that are supported by a multi wafer tray (the multi wafer tray) that belongs to a multi wafer support device MWSD.

Using the multi wafer tray virtually divides the load and unload overhead over the multiple wafers. The multi wafer tray can be shaped (especially its cavities may be shaped) to force wafers placed on the multi wafer tray to be aligned, mechanically, when inserted into the grooves—thus reducing alignment period. Using the multi wafer tray may reduce the overall time required for identifying the multiple wafers (ID reading) as identifying the multiple wafers that are supported by the multi wafer tray does not require moving the ID reader from a remote location each time a wafer should be identified. The MWSD may be placed into a cassette to ensure minimum exchange time.

According to an embodiment of the invention the multiple wafers are supported by a MWSD that has a chuck, wherein the MWSD facilitates backside illumination and may allow backside imaging of the wafers.

The MWSD may use vacuum holes or channels to provide areas of low pressure in proximity to the multiple wafers and thus may flatten the wafers. Especially, the wafers can be flattened so that their bow is below a depth of focus of optics that image the multiple wafers.

According to an embodiment of the invention the backside of the multiple wafers are supported by flexible elements such as flexible bottom elements that allow flattening the wafers by applying vacuum by the chuck of the MWSD. Thus, the flatness level of the wafers can be substantially similar to the flatness level that can be obtained by a chuck.

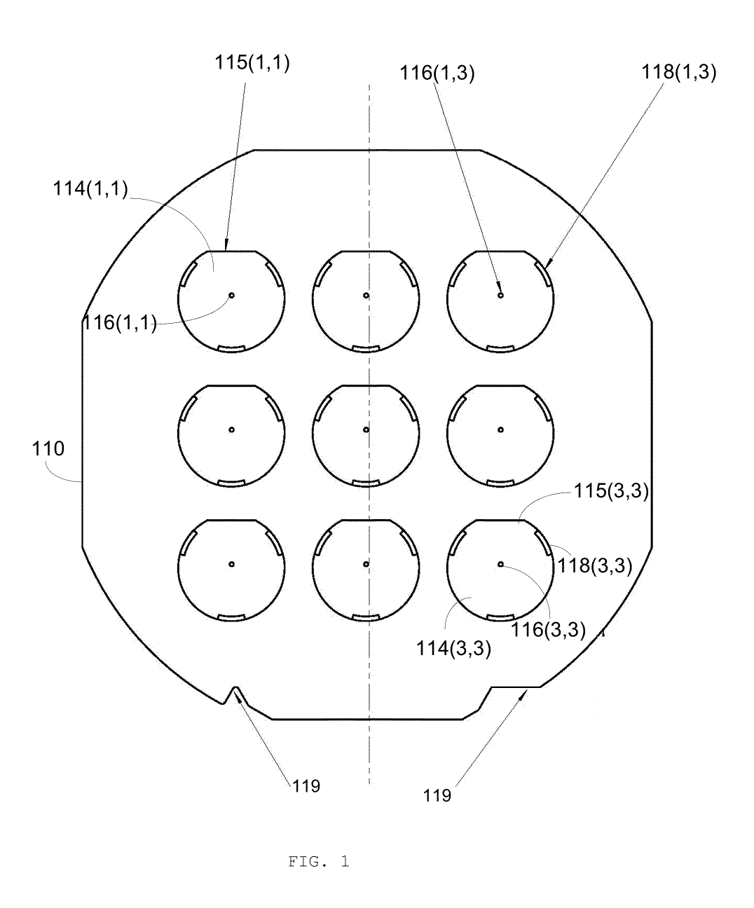

FIG. 1 illustrates a multi wafer tray 110 according to an embodiment of the invention. The multi tray wafer 110 may support nine wafers that are arranged in grid of three rows and three columns. The number of wafer supported by the multi tray wafer 110 may differ from nine and their arrangement may differ from grid arrangement of FIG. 1.

The multi wafer tray 110 has nine cavities 115(1,1)-115(3,3), each cavity is shaped to allow a wafer to be place in that cavity. Each cavity can be of the same size and shape of a wafer or can be slightly bigger than a wafer. Each cavity can be shaped in a manner to prevent the wafers from rotating or otherwise perform misalignments movements. This can be achieved by providing cavities that are not ideally rotationally symmetric—for example having a rounded shape that includes a flat portion—that corresponds to the notch or flat of the wafer.

Each cavity may be defined by one or more sidewalls and a bottom element such as bottom elements 114(1,1)-114(3,3). Vacuum or low pressure can be applied to the backside of a wafer that is within a cavity by one or more vacuum holes that may be formed in the bottom element. FIG. 1 illustrates a single vacuum hole per cavity (116(1,1)-116(3,3)) that is located at the center of each cavity but the location of the hole and the number of vacuum holes can changes from those illustrated in FIG. 1.

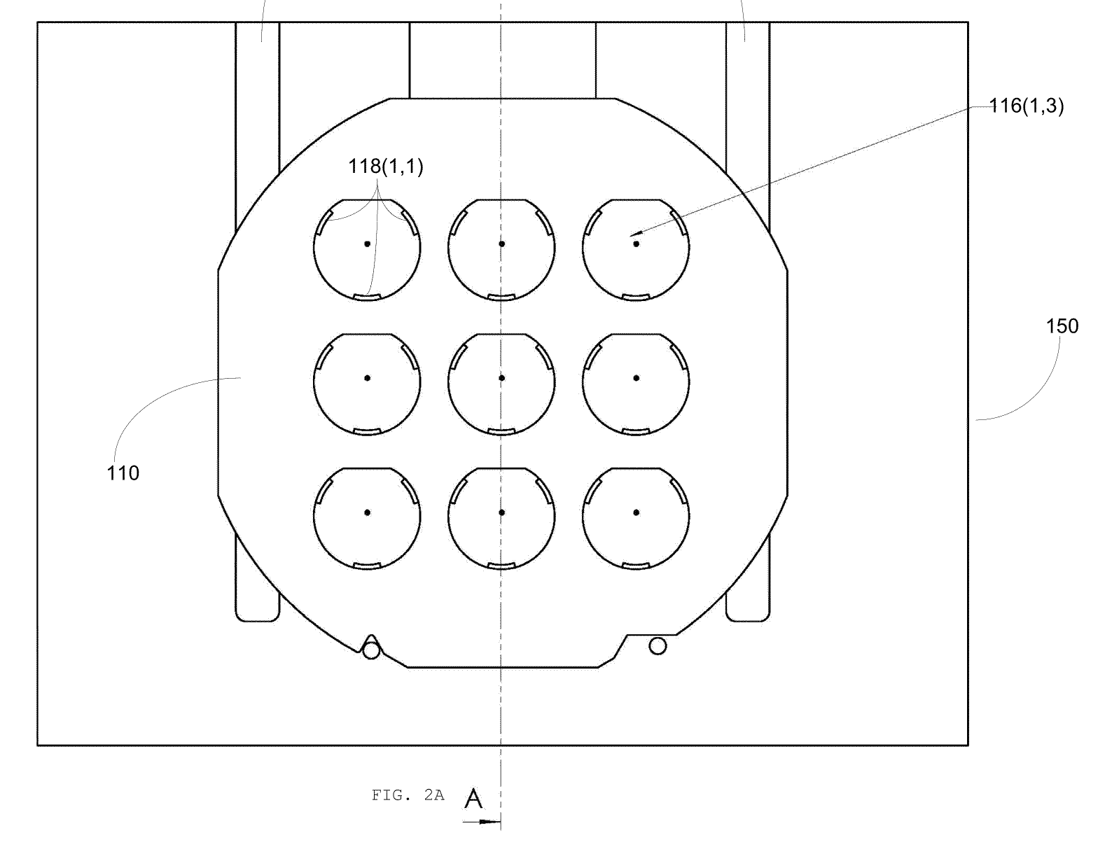

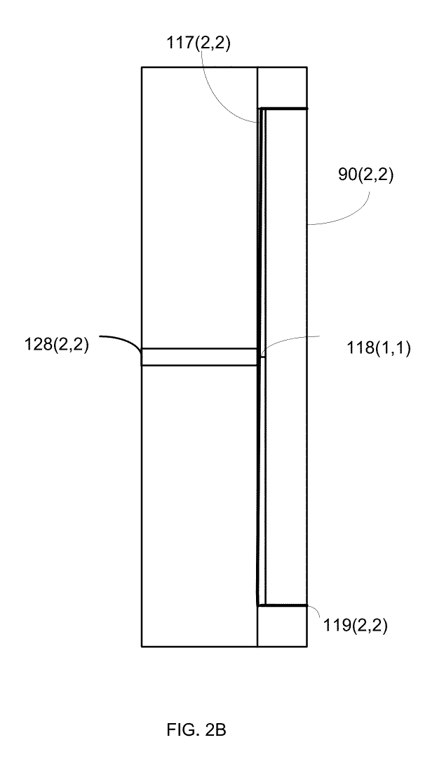

FIG. 2A illustrates a multi wafer tray 110 and a frame 150 according to an embodiment of the invention.

Multi wafer tray 110 is illustrated in FIG. 2A as including wafer stopper elements 118(1,1)-118(3,3) that are located at the bottom of each cavity and are relatively small in relation to the entire cavity such as to contact only a small area (for example—between 5 and 15 percent) of a wafer.

FIG. 2A illustrates three annular wafer stopper elements 118(1,1) that are located at about one hundred and twenty degrees from each other but the number, shape and size of these wafer stopper elements can differ from those illustrated in FIG. 2A. FIG. 2A also illustrates vacuum holes 116(1,1)-116(3,3)—these may be formed in the chuck (located below the multi wafer tray 110) and on in the multi wafer tray 110 or may be formed in both the chuck and in the multi wafer tray 110.

FIG. 2B is a cross sectional view of a portion of a multi wafer support device 100 and of a wafer 90(2,2) according to an embodiment of the invention.

The cross sectional view illustrates wafer 90(2,2) that is located in cavity 115(1,1), being supported by a bottom element 117(2,2) that has a single vacuum hole 119(2,2) that ends a vacuum tunnel 128(2,2) defined in chuck 120 of the multi wafer support device 100.

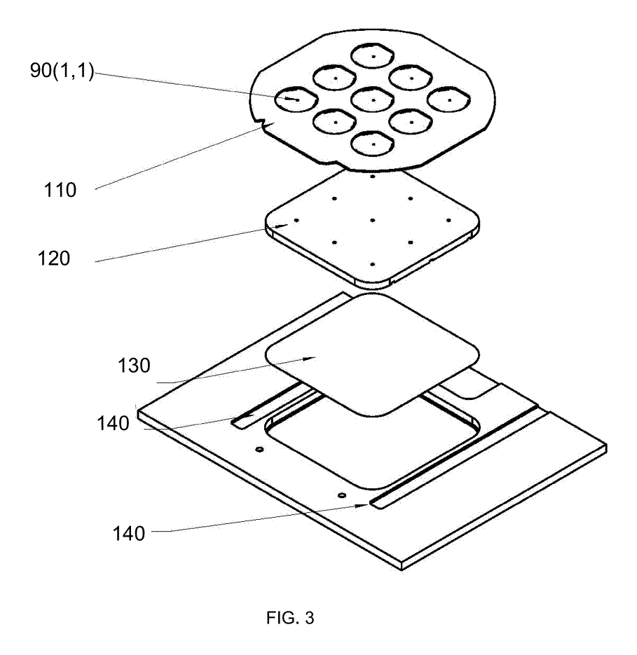

FIG. 3 is exploded view of a multi wafer support device 100 and of a frame 150 according to an embodiment of the invention.

The multi wafer support device 100 may include the multi wafer tray 110, a chuck 120, and bottom interfacing element 130. The frame 150 may include grooves 140 that that may be arranged to receive interfacing elements of a load and unload mechanism, wherein the bottom interfacing element 130 may be arranged to support the chuck 120 and to be placed above the grooves 140.

The multi wafer tray 110 can be bigger then the chuck 120 and the bottom interfacing element 130. According to an embodiment of the invention the chuck 120 and the bottom interfacing element 130 can fit to a space defined between the grooves 140 while the multi wafer tray 110 may exceed this space and have an exterior portion that “covers” the grooves.

Chuck 120 of FIG. 3 is flat and includes a single vacuum hole per wafer.

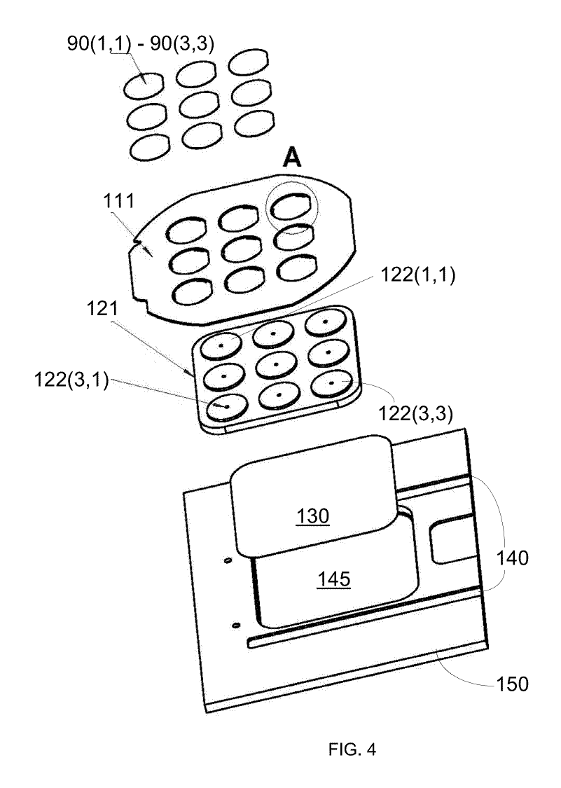

FIG. 4 is exploded view of a multi wafer support device 102 and of a frame 150 according to an embodiment of the invention.

The multi wafer support device 100 may include the multi wafer tray 110, a chuck 121 and a bottom interfacing element 130.

Chuck 121 of FIG. 4 includes a flat background surface 123 and multiple mounts 122(1,1)-122(3,3), each mount is shaped to enter a cavity and may have one or more vacuum holes for introducing vacuum in proximity to a wafer located in the cavity. Each mount may be shaped to exactly fit the bottom of the cavity or may be slightly smaller than the bottom of the cavity. Alternatively, multiple mounts can fit in a single cavity. A mount may contact a backside of a wafer (located in a cavity), may replace a bottom element of the multi wafer tray, may contact a bottom element of the multi wafer tray, or may contact a wafer stopping element. A mount can be transparent, at least partially opaque, can include an illumination element, can include transparent and non-transparent regions, can be stiff, can be flexible, or can include flexible regions.

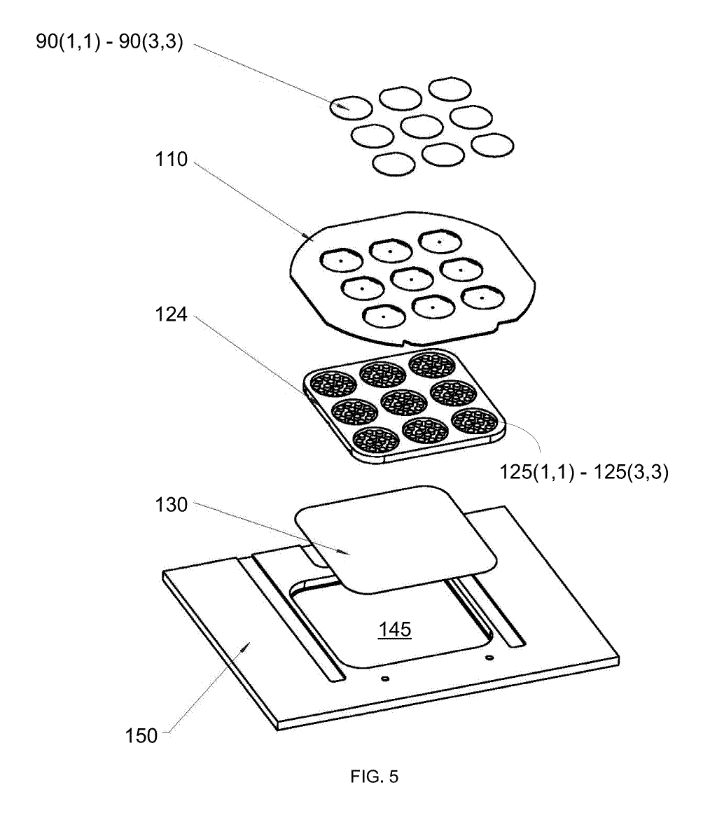

FIG. 5 is exploded view of a multi wafer support device 103 and of a frame 150 according to an embodiment of the invention.

The multi wafer support device 100 may include the multi wafer tray 110, a chuck 124 and a bottom interfacing element 130.

Chuck 124 of FIG. 5 includes a flat background surface 124(1) and multiple illumination elements 125(1,1)-125(3,3). Each illumination element may be shaped to enter a cavity and may illuminate the backside of a wafer located in the cavity. At least a portion of the backside of the wafer may be viewed by an imager positioned below the wafer. This may be facilitated by having a transparent chuck, a chuck having transparent regions and having illumination elements shaped such that they to not mask the entire wafer. Alternatively, the wafer may be transparent and the light that passes through the wafer can be detected by one or more light sensors positioned above the wafer.

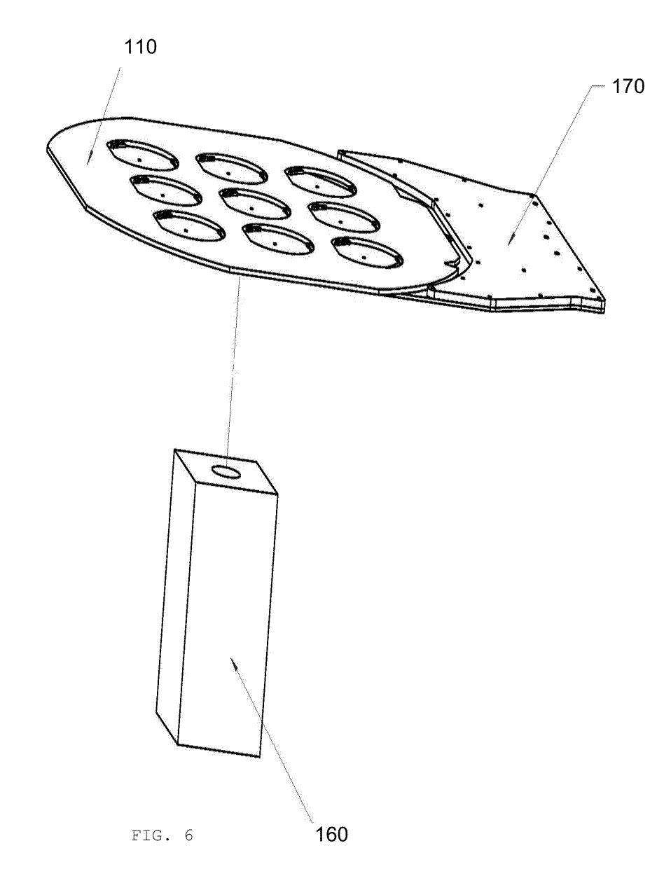

FIG. 6 illustrates a wafer identification unit 160, a multi wafer tray 110 and an end effector 170 according to an embodiment of the invention.

The a wafer identification unit 160 may image the backside of wafers supported by the multi wafer tray 110. The wafer identification unit 160 may illuminate the backside of wafers supported by the multi wafer tray 110 and read identification information about each wafer, using OCR methods. The end effector 160 includes two spaced apart and narrow interfacing elements that can fit the grooves 140 of the chuck. These two spaced apart and narrow interfacing elements are not shown in FIG. 6 as they are “covered” by the wafer.

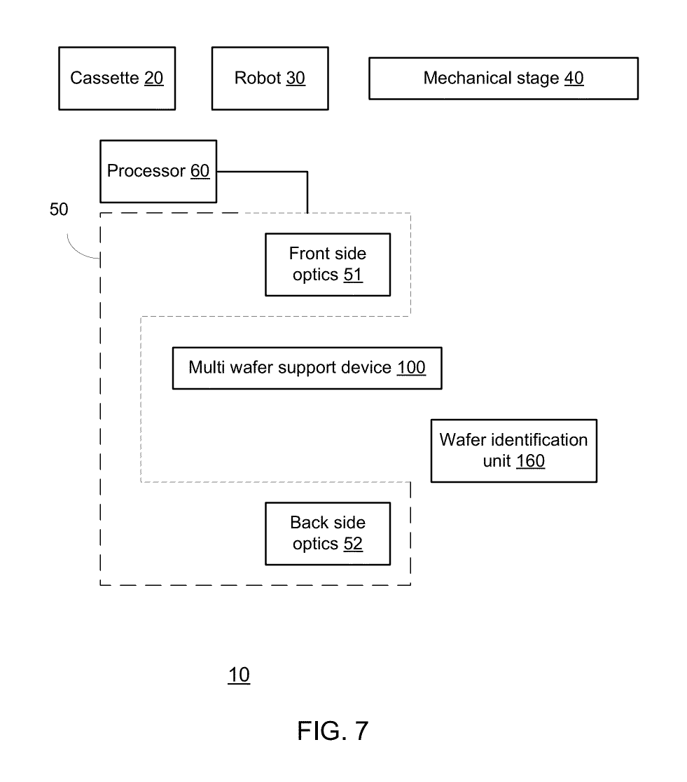

FIG. 7 illustrates an inspection system 10 according to an embodiment of the invention.

Inspection system 10 includes: (a) a cassette 20 for housing multi wafer support devices; (b) a robot 30 for transferring a multi wafer support device between the cassette and the frame 150, optional (c) wafer identification unit 160 such as OCR/ID reader that may identify wafers based upon identification information printed on the wafers, (d) a mechanical stage 40 that may include the frame 150 and one or more motors, the mechanical stage 40 may be arranged to introduce movement between the multi wafer support device and optics 50; (e) optics 50 that may be arranged to acquire images of the multiple wafers supported by the multi wafer support element, the optical can include illumination optics and collection optics, (f) a processor 60 arranged to process the images acquired by the optics, the processing may include defect detection, alignment, wafer to wafer comparison, verification and the like. Inspection system 10 may include the multi wafer support device 100.

The optics 50 can include at least one out of backside illumination optics, front side illumination optics, pulsed illumination optics, continuous illumination optics, backside collection optics, front side collection optics, non-continuous activated collection optics, continuous collection optics, dark field optics, bright field optics, visible light optics, infra red optics, near infra red optics, ultra violet optics, broadband optics, narrowband optics, and the like. For simplicity of explanation FIG. 7 illustrates backside optics 51 and front side optics 52.

The cassette 20 and the robot 30 may be a part of a load and unload mechanism 70.

The multi wafer tray 110 may have an exterior that may be shaped and sized as a larger wafer that is much larger than the wafers supported by the multi wafer tray—thus allowing it to be stored in cassettes that are designed to store such larger wafers and be manipulated by robots that are arranged to manipulate larger wafers.

Wafers may be put into the multi wafer tray manually or automatically (the wafers may be aligned in the multi wafer tray so no need for PAL), the multi wafer tray 110 can then be put into the cassette 20, robot 30 can will take the multi wafer tray and place it over the wafer identification unit 160, the identification (OCR) sequence can be applied either step by step for each wafer or for all the wafers supported by the multi wafer tray 110 (one or more images can be acquired); the multi wafer tray 100 can be placed on the chuck and the inspection process can start.

The multi wafer tray 110 may be constructed in such a way to enable back light illumination for each wafer while scanning better detect certain defects.

The multi wafer tray 110 may be constructed in such a way as to flatten the wafers supported by it and be less sensitive to focus variations.

Scanning of wafers can be done either wafer by wafer or scanning by strips where each strip will contain sub-strips from different wafers

Each wafer will have its own results file/map.

After finishing inspection the multi wafer tray will be removed from the chuck and put into cassette. In some cases the multi wafer tray may be unloaded manually.

The chuck will be constructed in such a way that the multi wafer tray can be placed on a transparent or solid plate of the chuck. On the solid plate there may be holes for vacuum and on the bottom side there are channels for vacuum transportation. The channels may be covered with transparent or solid cover.

The chuck can be built in such a way that the wafers are placed on mounts that are very flat and with vacuum holes.

The illumination can be outer back light or lighting inside the chuck (LED for example) in case of back light.

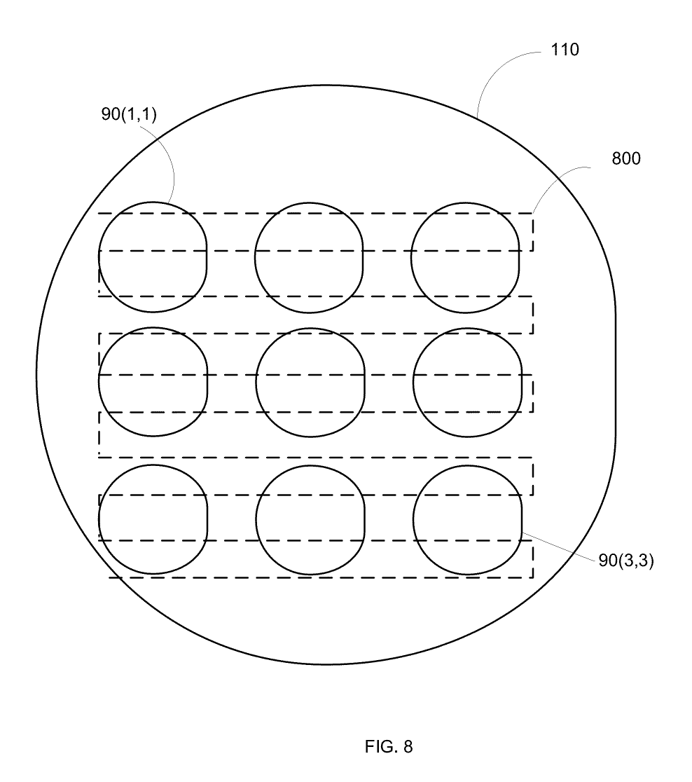

FIG. 8 illustrates a scanning pattern 200 according to an embodiment of the invention.

Scanning pattern 200 is a raster scanning pattern which each slice of the raster scanning includes images of portions of wafers that may belong to the same column

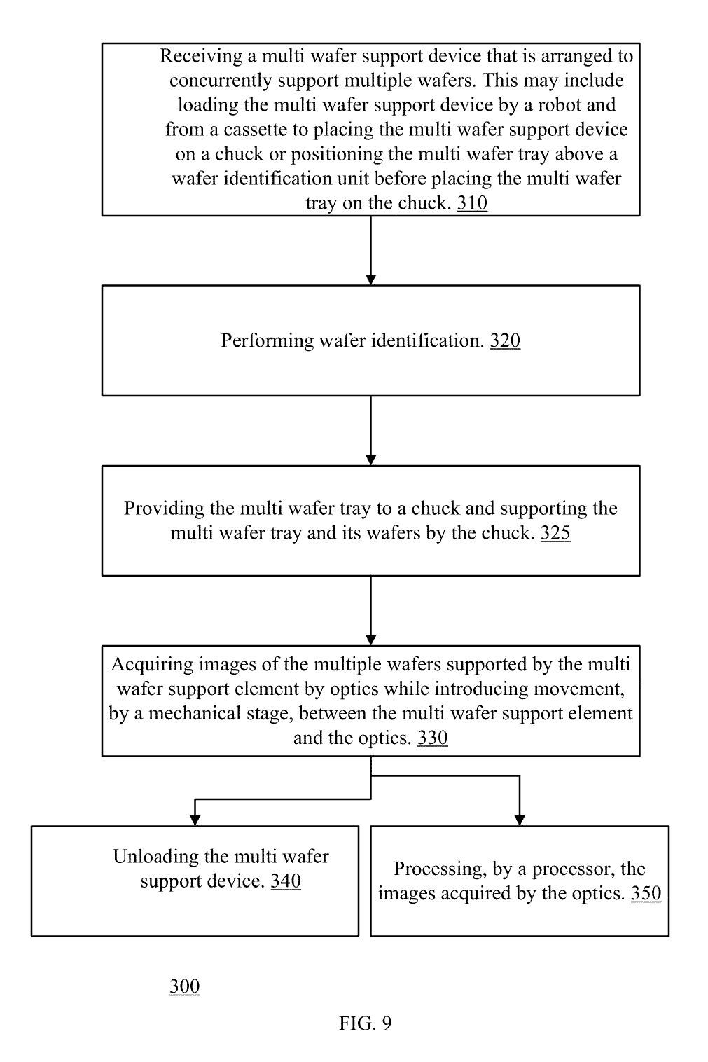

FIG. 9 illustrates method 300 according to an embodiment of the invention.

Method 300 may start by stage 310 of receiving a multi wafer support device that is arranged to concurrently support multiple wafers. This may include loading the multi wafer support device by a robot and from a cassette to placing the multi wafer support device on a chuck or positioning the multi wafer tray above a wafer identification unit before placing the multi wafer tray on the chuck.

Stage 310 may be followed by stage 320 of performing wafer identification.

Stage 320 may be followed by stage 325 of providing the multi wafer tray to a chuck and supporting the multi wafer tray and its wafers by the chuck. The supporting can continue during stage 330.

Stage 325 may be followed by stage 330 of acquiring images of the multiple wafers supported by the multi wafer support element by optics while introducing movement, by a mechanical stage, between the multi wafer support element and the optics.

Stage 330 may include scanning, by the optics, one wafer after the other.

Stage 330 may include scanning, by the optics, multiple portions of a plurality of wafers before completing a scan of an entire single wafer.

Stage 330 may be followed by stage 340 and 350.

Stage 340 may include unloading the multi wafer support device.

Stage 350 may include processing, by a processor, the images acquired by the optics.

The multi wafer support device may include a multi wafer tray and a chuck, the chuck may be transparent and the multi wafer tray defines multiple cavities for receiving the multiple wafers without concealing a backside of the multiple wafers. Stage 320 and, additionally or alternatively, stage 330 may include illuminating, by a backside illumination unit, a backside of the multiple wafers.

The multi wafer support device may include a multi wafer tray and a chuck. The chuck may be transparent and the multi wafer tray may define multiple cavities for receiving the multiple wafers. The multi wafer tray may have, at a bottom of each of the cavities, a transparent and flexible bottom element that contacts the transparent chuck. Stage 325 may include stage flattening, by the chuck, the transparent and flexible bottom element of each cavity and flattening each wafer supported by each transparent and flexible bottom element.

The multi wafer support device may include a multi wafer tray and a chuck. The multi wafer tray may define multiple cavities for receiving the multiple wafers. The multi wafer tray has, at a bottom of each of the cavities, a flexible bottom element that contacts the transparent chuck. Stage 325 may include flattening, by the chuck, the flexible bottom element of each cavity and each wafer supported by each flexible bottom element.

Stage 320 and additionally or alternatively stage 330 may include illuminating the multiple wafers by at least one illumination element of the chuck.

The multi wafer support device may include a chuck, a multi wafer tray, a bottom interfacing element and a frame. The frame may include grooves that are arranged to receive interfacing elements of a load and unload mechanism. The bottom interfacing element may be arranged to support the chuck and to be placed above the grooves. Stage 325 may include placing, by the load and unload mechanism, the multi wafer tray, the chuck and bottom interfacing element on the frame while contacting the bottom interfacing element; and withdraw the interfacing elements from the grooves.

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

It would be appreciated by those skilled in the art that the term wafer (singular or plural) can be replaced by any other unit to be inspected.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

We claim:

1. An inspection system, comprising:
a multi wafer support device arranged to concurrently support multiple wafers;
optics arranged to acquire images of the multiple wafers supported by the multi wafer support element;
a mechanical stage arranged to introduce movement between the multi wafer support element and the optics; and
a processor arranged to process the images acquired by the optics.

2. The inspection system according to claim 1, wherein the multi wafer support device comprises a multi wafer tray and a chuck.

3. The inspection system according to claim 2, wherein the chuck is transparent and the multi wafer tray defines multiple cavities for receiving the multiple wafers without concealing a backside of the multiple wafers.

4. The inspection system according to claim 3, comprising a backside illumination unit arranged to illuminate a backside of the multiple wafers.

5. The inspection system according to claim 3, wherein the multi wafer tray has, at a bottom of each of the cavities, a transparent and flexible bottom element that contacts the transparent chuck.

6. The inspection system according to claim 5, wherein the chuck is arranged to flatten the transparent and flexible bottom element of each cavity and to flatten each wafer supported by each transparent and flexible bottom element.

7. The inspection system according to claim 5, wherein the multi wafer tray has, at a bottom of each of the cavities, a transparent bottom element that contacts the transparent chuck.

8. The inspection system according to claim 2, wherein the multi wafer tray defines multiple cavities for receiving the multiple wafers and the multi wafer tray has, at a bottom of each of the cavities, a flexible bottom element that contacts the transparent chuck.

9. The inspection system according to claim 7, wherein the chuck is arranged to flatten the flexible bottom element of each cavity and to flatten each wafer supported by each flexible bottom element.

10. The inspection system according to claim 2, wherein the chuck is at least partially opaque.

11. The inspection system according to claim 2, wherein the chuck comprises at least one illumination element arranged to illuminate the multiple wafers.

12. The inspection system according to claim 2, wherein the multi wafer support device further comprising a bottom interfacing element and a frame , the frame comprises grooves that are arranged to receive interfacing elements of a load and unload mechanism, wherein the bottom interfacing element is arranged to support the chuck and to be placed above the grooves.

13. The inspection system according to claim 12, comprising the load and unload mechanism, wherein the load and unload mechanism is arranged to place the multi wafer tray, the chuck and bottom interfacing element on the frame while contacting the bottom interfacing element and then withdraw from the grooves.

14. The inspection system according to claim 2, wherein the multi wafer tray is arranged to support multiple wafers that are spaced apart from each other and are arranged in a two-dimensional array.

15. The inspection system according to claim 1, wherein the optics are arranged to scan one wafer after the other.

16. The inspection system according to claim 1, wherein the optics are arranged to scan multiple portions of a plurality of wafers before completing a scan of an entire single wafer.

17. A method for inspecting multiple wafers, the method comprises:
receiving a multi wafer support device that is arranged to concurrently support multiple wafers;
acquiring images of the multiple wafers supported by the multi wafer support element by optics while introducing movement, by a mechanical stage, between the multi wafer support element and the optics; and
processing, by a processor, the images acquired by the optics.

18. The method according to claim 17, wherein the multi wafer support device comprises a multi wafer tray and a chuck; wherein the chuck is transparent and the multi wafer tray defines multiple cavities for receiving the multiple wafers without concealing a backside of the multiple wafers; and the method comprises illuminating, by a backside illumination unit, a backside of the multiple wafers.

19. The method according to claim 17, wherein the multi wafer support device comprises a multi wafer tray and a chuck; wherein the chuck is transparent and the multi wafer tray defines multiple cavities for receiving the multiple wafers; wherein the multi wafer tray has, at a bottom of each of the cavities, a transparent and flexible bottom element that contacts the transparent chuck; and wherein the method comprises flattening, by the chuck, the transparent and flexible bottom element of each cavity and flattening each wafer supported by each transparent and flexible bottom element.

20. The method according to claim 17, wherein the multi wafer support device comprises a multi wafer tray and a chuck; wherein the multi wafer tray defines multiple cavities for receiving the multiple wafers and the multi wafer tray has, at a bottom of each of the cavities, a flexible bottom element that contacts the transparent chuck; and wherein the method comprises flattening, by the chuck, the flexible bottom element of each cavity and each wafer supported by each flexible bottom element.

21. The method according to claim 17, wherein the multi wafer support device comprises a multi wafer tray and a chuck; wherein the method comprises illuminating the multiple wafers by at least one illumination element of the chuck.

22. The method according to claim 17, wherein the multi wafer support device comprises a chuck, a multi wafer tray, a bottom interfacing element and a frame , the frame comprises grooves that are arranged to receive interfacing elements of a load and unload mechanism, wherein the bottom interfacing element is arranged to support the chuck and to be placed above the grooves; wherein the method comprises placing, by the load and unload mechanism, the multi wafer tray, the chuck and bottom interfacing element on the frame while contacting the bottom interfacing element; and withdraw the interfacing elements from the grooves.

23. The method according to claim 17, comprising scanning, by the optics, one wafer after the other.

24. The method according to claim 17, comprising scanning, by the optics, multiple portions of a plurality of wafers before completing a scan of an entire single wafer.

25. A multi wafer support device, comprising a multi wafer tray and a chuck;
wherein the multi wafer tray defines multiple cavities for receiving multiple wafers; wherein the multi wafer tray has, at a bottom of each of the cavities, a flexible bottom element that contacts the chuck; wherein the chuck is arranged to flatten the flexible bottom element of each cavity.

26. The multi wafer support device according to claim 25, wherein the chuck is at least partially opaque.

27. The multi wafer support device according to claim 25, wherein the chuck comprises at least one illumination element arranged to illuminate the multiple wafers.

28. The multi wafer support device according to claim 25, wherein the multi wafer support device further comprising a bottom interfacing element and a frame , the frame comprises grooves that are arranged to receive interfacing elements of a load and unload mechanism, wherein the bottom interfacing element is arranged to support the chuck and to be placed above the grooves.

29. The multi wafer support device according to claim 25, wherein the chuck is transparent and wherein each of the flexible bottom elements is transparent.

30. A multi wafer support device, comprising a multi wafer tray and a chuck; wherein the chuck is transparent and the multi wafer tray defines multiple cavities for receiving the multiple wafers without concealing a backside of the multiple wafers.

31. The multi wafer support device according to claim 30, wherein the multi wafer tray has, at a bottom of each of the cavities, a transparent bottom element that contacts the chuck.

32. The multi wafer support device according to claim 31 wherein each transparent bottom element is flexible and the chuck is arranged to flatten the flexible bottom element of each cavity and to flatten the wafer supported by the flexible bottom element.
